(19) United States
(12) Patent Application Publication
(10) Pub. No.: US 2008/0164562 A1
(43) Pub. Date: Jul. 10, 2008

(54) SUBSTRATE WITH EMBEDDED PASSIVE ELEMENT AND METHODS FOR MANUFACTURING THE SAME

(75) Inventors: Yung-Hui Wang, Kaohsiung (TW); Ying-Te Ou, Kaohsiung (TW); Chih-Pin Hung, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: ADVANCED SEMICONDUCTOR ENGINEERING, INC., Kaohsiung (TW)

(21) Appl. No.: 11/939,797

(22) Filed: Nov. 14, 2007

(30) Foreign Application Priority Data
Jan. 10, 2007 (TW) 096100976

(51) Int. Cl. H01L 21/441; H01L 29/92

(52) U.S. Cl. 257/528; 438/381; 257/E29.342; 257/E21.477

(57) ABSTRACT

A substrate with an embedded passive element and methods for manufacturing the same are provided, wherein the substrate includes an interlayer circuit board having a first conductive circuit, a dielectric layer, a first electrode, a second electrode, and a second conductive circuit. The dielectric layer formed on the interlayer circuit board has a first recess and a second recess for respectively accommodating the first electrode and the second electrode. The embedded passive element is formed by the first electrode, the second electrode, and the dielectric layer between the first electrode and the second electrode. The second conductive circuit electrically connects the first electrode and the second electrode.

### BACKGROUND OF THE INVENTION

1. Field of the Invention

The present invention relates to a package structure and methods for manufacturing the same, and more particularly to a substrate with an embedded passive element and methods for manufacturing the same.

2. Description of the Related Art

The embedded capacitor structure is formed by embedding a dielectric material into a substrate using multiple stacked package (MSP) technique according to circuit characteristics and requirements of a module. In practical application, on the basis of the circuit characteristics and requirements, substrate materials having different dielectric coefficients and resistances are adopted to be applied to designs of embedded capacitors, resistors, high-frequency transmission lines, or the like. With package integration of the embedded device substrate technique, circuit layout is scaled down, and signal transmission distance is shortened to enhance the working performance of the entire device, so the conventional discrete passive elements, such as capacitors, resistors, and inductors are substituted. The advantages thereof include reducing the amount of the discrete passive elements, so as to lower the relevant fabrication and inspection costs of the product, reduce the thickness of the substrate, and reduce the amount of the pads of the device, thereby enhancing the electrical high-frequency response of the module to improve the packaging density and reliability of the product.

Take an embedded capacitor for example. Conventional embedded capacitors can be divided into two main types, namely mental-insulator-mental (MIM) capacitors and vertically-interdigitated-capacitors (VICs). The MIM capacitor is formed by an upper and a lower metal plates 101a and 101b between multilayer circuit boards 100 (as shown in FIG. 1). The VIC (as shown in FIG. 2) is formed by a plurality of interdigitated metal plates 201a, 201b, 201c, and 201d between multilayer circuit boards 200. In order to improve the capacitance characteristic of the embedded capacitor, both types require increasing the amount of the laminated layers in the capacitor structure (metal plate and multilayer circuit board), which not only takes up the limited substrate space, but also increases the thickness of the substrate sharply.

Therefore, a progressive embedded capacitor structure and methods for manufacturing the same are needed to enhance the capacitance characteristic of the embedded capacitor without increasing the thickness of the substrate, thus solving the conventional embedded capacitor's problem of greatly increasing the thickness of the substrate while enhancing the capacitance characteristic.

### SUMMARY OF THE INVENTION

The object of the present invention is to provide a substrate with an embedded passive element, which includes an interlayer circuit board having a first conductive circuit, a dielectric layer, a first electrode, a second electrode, and a second conductive circuit. The dielectric layer formed on the interlayer circuit board has a first recess and a second recess for respectively accommodating the first electrode and the second electrode. The embedded passive element is formed by the first electrode, the second electrode, and the dielectric layer between the first electrode and the second electrode. The second conductive circuit electrically connects the first electrode and the second electrode.

Another object of the present invention is to provide a method for manufacturing the substrate with an embedded passive element. The method includes the following steps. First, an interlayer circuit board having a first conductive circuit is provided. Then, a dielectric layer is formed on the interlayer circuit board. Afterwards, a first recess and a second recess are formed in the dielectric layer. Then, the conductive material is filled into the first recess and the second recess to respectively form a first electrode and a second electrode, whereby the embedded passive element is formed by the first electrode, the second electrode, and the dielectric layer between the first electrode and the second electrode. Finally, a second conductive circuit is formed on the first electrode and the second electrode.

Still another object of the present invention is to provide a method for manufacturing the substrate with an embedded passive element. The method includes the following steps. First, an interlayer circuit board having a first conductive circuit disposed thereon is provided and a metal sheet having a dielectric layer disposed on its surface is then provided. Then, the metal sheet is laminated onto the interlayer circuit board, whereby the dielectric layer contacts the first conductive circuit on the interlayer circuit board. Afterwards, a first recess and a second recess are formed in the metal sheet and the dielectric layer. Then, the conductive material is filled into the first recess and the second recess to form a first electrode and a second electrode, whereby the embedded passive element is formed by the first electrode, the second electrode, and the dielectric layer between the first electrode and the second electrode. Finally, a second conductive circuit is formed on the first electrode and the second electrode.

According to the present invention, one embedded passive element is formed by two electrodes embedded on the same side of the dielectric layer, a dielectric layer between the two electrodes, and a circuit for connecting the two electrodes, thus reducing the amount of laminated layers of the substrate, scaling down the circuit layout, and shortening the signal transmission distance to save the wiring space. Thus, the present invention is advantageous in not increasing the thickness of the substrate, and solves the problem of the conventional embedded passive element that the thickness of the substrate must be greatly increased when the working performance is enhanced.

### BRIEF DESCRIPTION OF THE DRAWINGS

FIG. 1 is a schematic structural view of a conventional MIM capacitor;

FIG. 2 is a schematic structural view of a conventional VIC;

FIG. 3 is a structural vertical-sectional view of a substrate 300 with an embedded capacitor 30 according to a preferred embodiment of the present invention;

FIG. 4A is a structural cross-sectional view of a substrate with an embedded capacitor according to a preferred embodiment of the present invention;

FIG. 4B is a structural cross-sectional view of another substrate with an embedded capacitor according to a preferred embodiment of the present invention;

FIG. 5 is a manufacturing flow chart of the substrate with an embedded passive element in FIG. 3 according to a preferred embodiment of the present invention; and

FIG. 6 is a manufacturing flow chart of the substrate with an embedded passive element in FIG. 3 according to another preferred embodiment of the present invention.

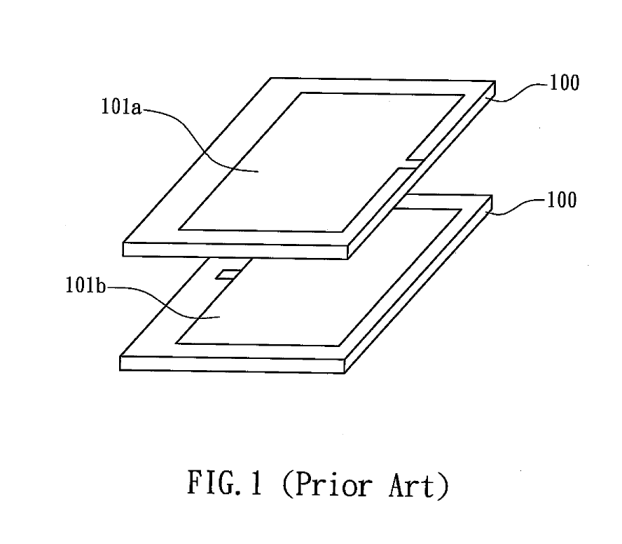

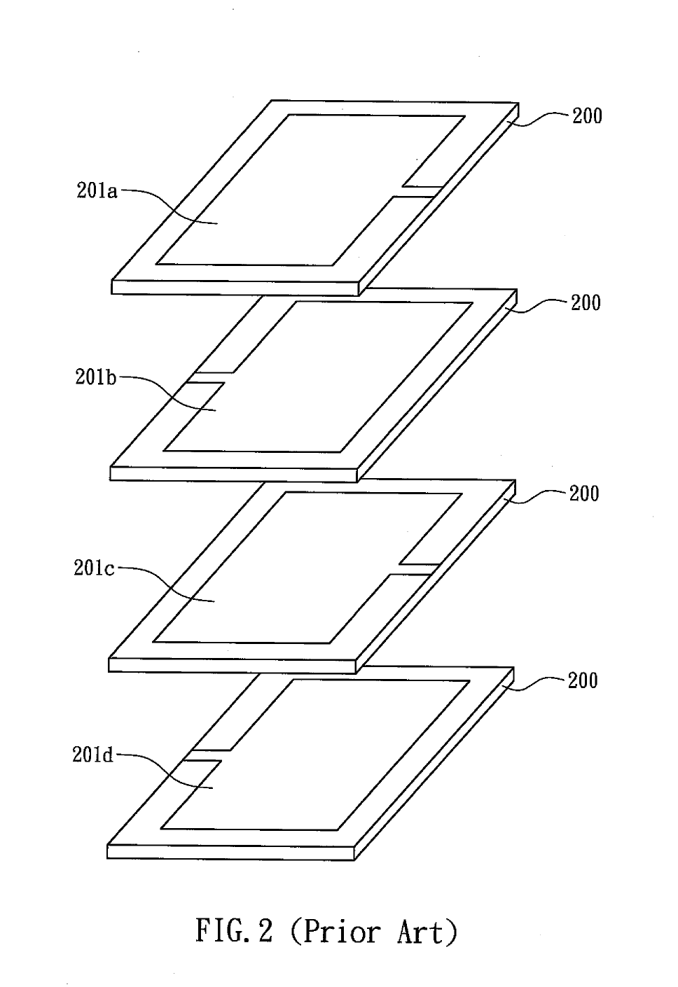

### DETAILED DESCRIPTION OF THE INVENTION

A substrate with an embedded passive element is provided in embodiments of the present invention. To make the aforementioned and other objectives, features and advantages comprehensible, a substrate 300 with an embedded capacitor 30 is taken as a preferred embodiment for illustration.

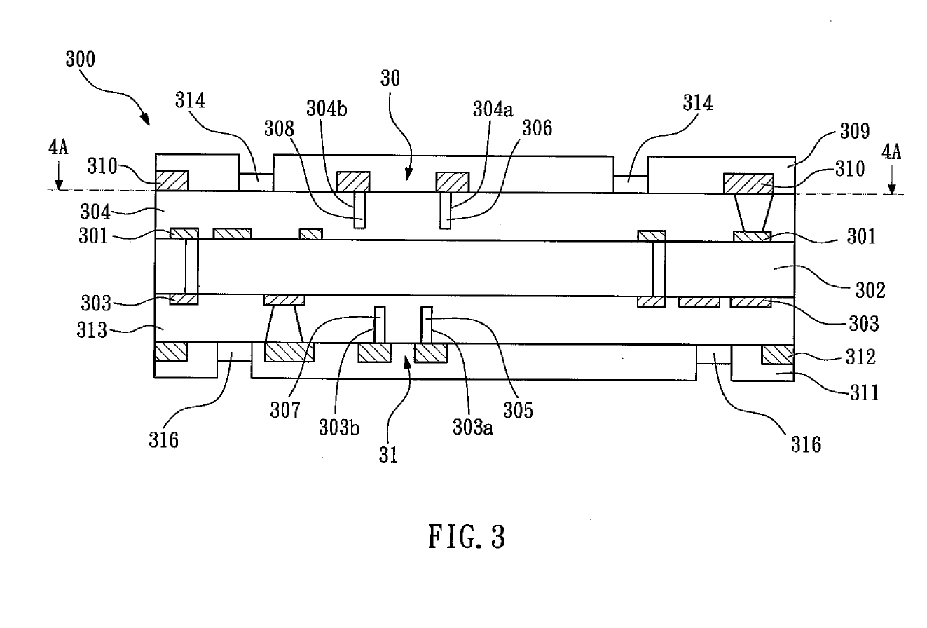

FIG. 3 shows a structural vertical-sectional view of a substrate 300 with an embedded capacitor 30 according to a preferred embodiment of the present invention. The substrate 300 includes: a lower laminated layer 313, an interlayer circuit board 302 having a first conductive circuit 301, a dielectric layer 304, a first electrode 306, a second electrode 308, and a second conductive circuit 310.

The interlayer circuit board 302 is a core layer (302) disposed on the lower laminated layer 313, and the first conductive circuit 301 is formed on the core layer (302). The lower laminated layer 313 is a dielectric layer. In some preferred embodiments of the present invention, a third conductive circuit 303 is further formed between the lower laminated layer 313 and the core layer (302). The first conductive circuit 301 and the third conductive circuit 303 are respectively formed in patterned conductive layers on the upper and lower sides of the core layer (302).

The dielectric layer 304 disposed on the interlayer circuit board 302 has a first recess 304a and a second recess 304b, and the first recess 304a and the second recess 304b are spaced a certain distance apart. The first electrode 306 is disposed in the first recess 304a, and the second electrode 308 is disposed in the second recess 304b.

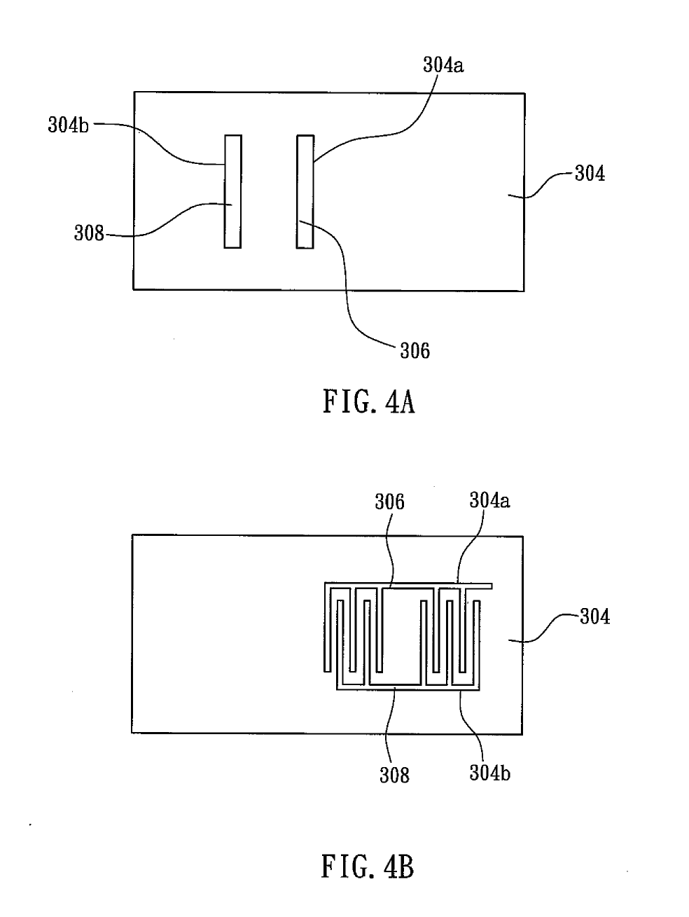

FIG. 4A shows a structural cross-sectional view of a substrate with an embedded capacitor according to a preferred embodiment of the present invention. In this embodiment, FIG. 4A is a cross-sectional view taken along a section line 4A-4A in FIG. 3. The first recess 304a and the second recess 304b are grooves or narrow holes formed by laser drilling or exposure development, and the grooves or narrow holes formed by the first recess 304a and the second recess 304b are parallel to each other. A conductive material is filled into the first recess 304a and the second recess 304b by screen printing or plating, whereby two parallel plate structures form the first electrode 306 and the second electrode 308.

In other embodiments of the present invention, the first recess 304a and the second recess 304b are comb narrow hole structures. In FIG. 4B, a structural cross-sectional view of another substrate with an embedded capacitor according to a preferred embodiment of the present invention is shown. In this embodiment, the first recess 304a and the second recess 304b are comb groove structures formed by laser drilling or exposure development. The comb groove structures of the first recess 304a and the second recess 304b are interdigitated. The conductive material is filled into the first recess 304a and the second recess 304b by screen printing or plating, so that two interdigitated plate comb structures form the first electrode 306 and the second electrode 308.

Further, in FIG. 3, the first electrode 306 and the second electrode 308 are electrically connected to other circuit layers through the second conductive circuit 310. The embedded capacitor 30 is formed by the first electrode 306, the second electrode 308, and the dielectric layer 304 disposed between the first electrode 306 and the second electrode 308. In a preferred embodiment of the present invention, the second conductive circuit 310 is formed on the dielectric layer 304, and is a patterned metal layer with a conducted loop for electrically connecting the first electrode 306 and the second electrode 308 to other circuits. By wire bonding (not shown), the second conductive circuit 310 is electrically connected to external portions (not shown) outside the substrate 300, such as dies, electronic devices, or other discrete passive elements.

It should be noted that the substrate 300 further has a second capacitor 31 formed in the lower laminated layer 313. In this embodiment, the second capacitor 31 (i.e., the embedded passive element) is formed by a third electrode 305, a fourth electrode 307, and the lower laminated layer 313 disposed between the third electrode 305 and the fourth electrode 307. The third electrode 305 is formed in a third recess 303a in the lower laminated layer 313, and the fourth electrode 307 is formed in a fourth recess 303b in the lower laminated layer 313.

The third recess 303a and the fourth recess 303b are formed in a surface opposite the surface of the lower laminated layer 313 in contact with the core layer (302), and the third recess 303a and the fourth recess 303b are spaced a certain distance apart. In addition, the third electrode 305 and the fourth electrode 307 are formed by filling a conductive material into the third recess 303a and the second recess 303b by plating or deposition, and are electrically connected with each other through the fourth conductive circuit 312. In this embodiment, the fourth conductive circuit 312 is a patterned metal layer with a conducted loop, which is formed in the surface of the lower laminated layer 313 having the third recess 303a and the fourth recess 303b disposed thereon, so as to connect the third electrode 305 and the fourth electrode 307.

Moreover, the substrate 300 further includes solder masks 309 and 311 respectively covering the second conductive circuit 310 and the fourth conductive circuit 312, whereby the parts of the second conductive circuit 310 and the fourth conductive circuit 312 for electrically connecting to external portions (not shown) are exposed by the solder masks 309 and 311, respectively. Metal layers 314 and 316 respectively cover the exposed portions of the second conductive circuit 310 and the fourth conductive circuit 312, serving as pads for subsequent wire bonding or flip chip process.

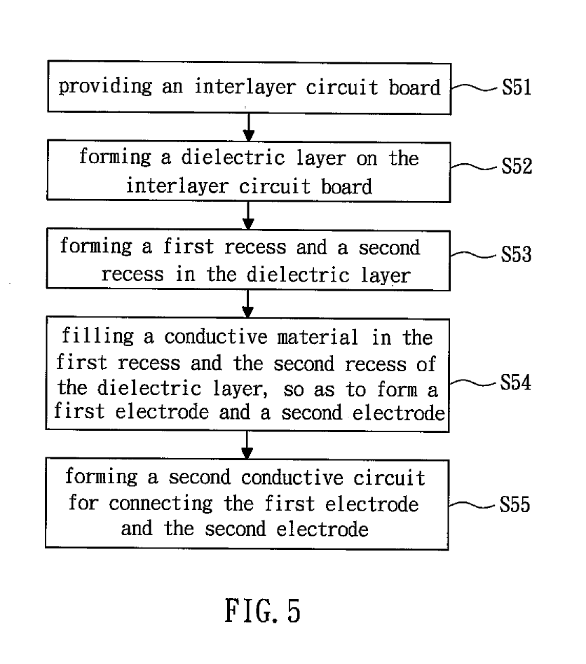

FIG. 5 shows a manufacturing flow chart of the substrate with an embedded passive element in FIG. 3 according to a preferred embodiment of the present invention. The process includes the following steps.

First, in Step S51, at least one interlayer circuit board 302 having a first conductive circuit 301 is provided. In the embodiment, the interlayer circuit board 302 includes a lower laminated layer 313 and a core layer (302), and serves as a core substrate in the multilayer circuit board package structure. However, in other embodiments, the interlayer circuit board 302 serves as a laminated plate in the multilayer circuit board package structure.

In Step S52, a dielectric layer 304 is formed on the interlayer circuit board 302. In a preferred embodiment of the present invention, the dielectric layer 304 is an upper laminated layer formed by hot pressing.

Next, in Step S53, a first recess 304a and a second recess 304b are formed in the dielectric layer 304 by, for example, laser drilling or exposure development. The shapes and sizes of the first recess 304a and the second recess 304b are not limited, and preferably are two parallel grooves or narrow holes, or two interdigitated comb groove structures.

Afterwards, in Step S54, a conductive material is filled into the first recess 304a and the second recess 304b of the dielectric layer 304 by screen printing or plating to respectively form the first electrode 306 and the second electrode 308, whereby an embedded passive element is formed by the first electrode 306, the second electrode 308, and the dielectric layer 304 between the first electrode 306 and the second electrode 308. In a preferred embodiment of the present invention, the first electrode 306 and the second electrode 308 are respectively formed by two parallel plate structures, or two interdigitated plate comb structures.

Then, in Step S55, a second conductive circuit 310 is formed on the first electrode 306 and the second electrode 308. The process of forming the second conductive circuit 310 includes depositing a conductive layer on one side of the dielectric layer 304 with the recesses 304a and 304b formed thereon, and then patterning the conductive layer into a patterned metal layer with a conducted loop, so as to electrically connect the first electrode 306 and the second electrode 308. In a preferred embodiment of the present invention, the conductive layer is formed at the same time as the first electrode 306 and the second electrode 308.

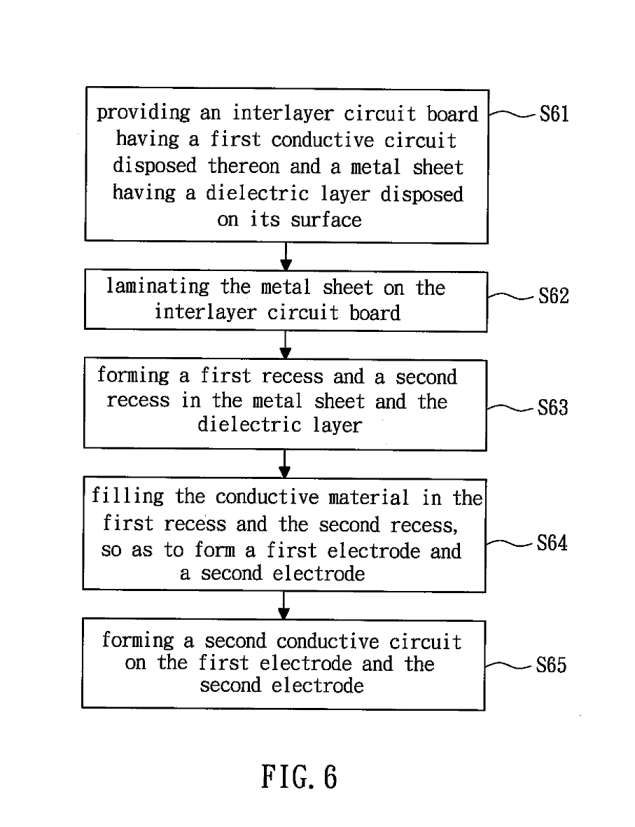

FIG. 6 shows a manufacturing flow chart of the substrate with an embedded passive element in FIG. 3 according to another preferred embodiment of the present invention. The process includes the following steps.

First, in Step S61, an interlayer circuit board 302 having a first conductive circuit 301 is provided, and a metal sheet having a dielectric layer 304 disposed on its surface is provided. In the embodiment, the interlayer circuit board 302 includes a lower laminated layer 313 and a core layer (302), and serves as a core substrate in the multilayer circuit board package structure. However, in other embodiments, the interlayer circuit board 302 serves as a laminated plate in the multilayer circuit board package structure. The dielectric layer 304 is formed by a prepreg for cladding the cover layer of the metal layer.

Next, in Step S62, the metal sheet is laminated onto the interlayer circuit board 302, whereby the dielectric layer 304 contacts the first conductive circuit 301 of the interlayer circuit board 302.

In Step S63, for example, a first recess 304a and a second recess 304b are formed in the dielectric layer 304 by, for example, laser drilling or exposure development. The shapes and sizes of the first recess 304a and the second recess 304b are not limited, and preferably are two parallel grooves or narrow holes, or two interdigitated comb groove structures.

Afterwards, in Step S64, a conductive material is filled into the first recess 304a and the second recess 304b of the dielectric layer 304 by screen printing or plating to respectively form the first electrode 306 and the second electrode 308, whereby an embedded passive element is formed by the first electrode 306, the second electrode 308, and the dielectric layer 304 between the first electrode 306 and the second electrode 308. In a preferred embodiment of the present invention, the first electrode 306 and the second electrode 308 are formed by two parallel plate structures, or two interdigitated plate comb structures.

Then, in Step S65, a second conductive circuit 310 is formed for electrically connecting the first electrode 306 and the second electrode 308. The process of forming the second conductive circuit 310 includes patterning the metal layer into a conducted loop, so as to electrically connect the first electrode 306 and the second electrode 308.

In addition, the process of forming the substrate 300 as shown in FIG. 3 further includes: forming a solder mask 309 to cover the second conductive circuit 310, wherein the parts of the second conductive circuit 310 for electrically connecting to external portions (not shown) are exposed by the solder mask 309. A metal layer 314 is formed on the exposed portions of the second conductive circuit 310, serving as a pad for subsequent wire bonding or flip chip process.

According to the preferred embodiments of the present invention, a conductive material in two recesses is formed in at least one dielectric layer on the interlayer circuit board, so as to form two separated electrodes. An embedded passive element is directly formed by two electrodes, a dielectric layer between the two electrodes, and a circuit conducting the two electrodes. As the two electrodes are directly embedded in a single dielectric layer, the capacitance characteristic of the embedded capacitor can be enhanced by increasing the number or density of the electrodes without increasing the amount of the layers of the interlayer circuit board, thus avoiding greatly increasing the thickness of the interlayer circuit board.

In the above embodiments, not only the circuit layout of the package substrate can be scaled down, but the signal transmission distance is shortened to save the wiring space. Thus, the present invention has the advantage of not increasing the thickness of the substrate, so as to solve the problem of the conventional embedded passive element that the working performance thereof cannot be enhanced without greatly increasing the thickness of the substrate. Further, as the electrodes that form the embedded passive element are all formed on the same side of the substrate, compared with the conventional embedded passive element, the present invention has a simple structure, and thus the process is simplified and the process cost is lowered.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A method for manufacturing a substrate with an embedded passive element, comprising:
providing an interlayer circuit board, having a first conductive circuit formed thereon;
forming a dielectric layer on the interlayer circuit board;
forming a first recess and a second recess in the dielectric layer;
filling a conductive material in the first recess and the second recess of the dielectric layer to form a first electrode and a second electrode, whereby the embedded passive element is formed by the first electrode, the second electrode, and the dielectric layer between the first electrode and the second electrode; and
forming a second conductive circuit on the first electrode and the second electrode.

2. The method for manufacturing a substrate with an embedded passive element as claimed in claim 1, further comprising:
forming a solder mask to cover the second conductive circuit, wherein a part of the second conductive circuit for electrically connecting to an external portion is exposed by the solder mask, and
forming a metal layer on the exposed part of the second conductive circuit.

3. The method for manufacturing a substrate with an embedded passive element as claimed in claim 1, wherein the recess is formed by laser drilling.

4. The method for manufacturing a substrate with an embedded passive element as claimed in claim 1, wherein the recess is formed by exposure development.

5. The method for manufacturing a substrate with an embedded passive element as claimed in claim 1, wherein the step of filling the conductive material is achieved by screen printing.

6. The method for manufacturing a substrate with an embedded passive element as claimed in claim 1, wherein the step of filling the conductive material is achieved by plating.

7. The method for manufacturing a substrate with an embedded passive element as claimed in claim 1, wherein the first and second electrodes have a plate structure respectively and are parallel to each other.

8. The method for manufacturing a substrate with an embedded passive element as claimed in claim 1, wherein the first electrode has a plurality of first plate comb structures, the second electrode has a plurality of second plate comb structures, and the first plate comb structures and the second plate comb structures are interdigitated.

9. A substrate with an embedded passive element, comprising:
an interlayer circuit board, having a first conductive circuit formed thereon;
a dielectric layer, disposed on the interlayer circuit board, and having a first recess and a second recess;
a first electrode, disposed in the first recess of the dielectric layer;
a second electrode, disposed in the second recess of the dielectric layer, whereby the embedded passive element is formed by the first electrode, the second electrode, and the dielectric layer between the first electrode and the second electrode; and
a second conductive circuit disposed on the first electrode and the second electrode.

10. The substrate with an embedded passive element as claimed in claim 9, further comprising:
a solder mask covering the second conductive circuit, wherein a part of the second conductive circuit for electrically connecting to an external portion is exposed by the solder mask; and
a metal layer disposed on the exposed part of the second conductive circuit.

11. The substrate with an embedded passive element as claimed in claim 9, wherein the first and second electrodes have a plate structure respectively and are parallel to each other.

12. The substrate with an embedded passive element as claimed in claim 9, wherein the first electrode has a plurality of first plate comb structures, the second electrode has a plurality of second plate comb structures, and the first plate comb structures and the second plate comb structures are interdigitated.

13. A method for manufacturing a substrate with an embedded passive element, comprising:
providing an interlayer circuit board, having a first conductive circuit formed thereon;
providing a metal sheet having a dielectric layer disposed on its surface;
laminating the metal sheet onto the interlayer circuit board, whereby the dielectric layer contacts the first conductive circuit on the interlayer circuit board;
forming a first recess and a second recess in the metal sheet and the dielectric layer;
filling the conductive material in the first recess and the second recess to form a first electrode and a second electrode, whereby the embedded passive element is formed by the first electrode, the second electrode, and the dielectric layer between the first electrode and the second electrode; and
forming a second conductive circuit on the first electrode and the second electrode.

14. The method for manufacturing the substrate with an embedded passive element as claimed in claim 13, wherein the dielectric layer is a prepreg.

15. The method for manufacturing the substrate with an embedded passive element as claimed in claim 13, further comprising:
forming a solder mask to cover the second conductive circuit, wherein a part of the second conductive circuit for electrically connecting to an external portion is exposed by the solder mask; and
forming a metal layer on the exposed part of the second conductive circuit.

16. The method for manufacturing the substrate with an embedded passive element as claimed in claim 13, wherein the recess is formed by laser drilling.

17. The method for manufacturing the substrate with an embedded passive element as claimed in claim 13, wherein the recess is formed by exposure development.

18. The method for manufacturing the substrate with an embedded passive element as claimed in claim 13, wherein the step of filling the conductive material is achieved by screen printing.

19. The method for manufacturing the substrate with an embedded passive element as claimed in claim 13, wherein the step of filling the conductive material is achieved by plating.

20. The method for manufacturing the substrate with an embedded passive element as claimed in claim 13, wherein the first and second electrodes have a plate structure respectively and are parallel to each other.

21. The method for manufacturing the substrate with an embedded passive element as claimed in claim 13, wherein the first electrode has a plurality of first plate comb structures, the second electrode has a plurality of second plate comb structures, and the first plate comb structures and the second plate comb structures are interdigitated.
